(19) United States
(12) Patent Application Publication
(10) Pub. No.: US 2010/0155135 A1
(43) Pub. Date: Jun. 24, 2010

(54) ILLUMINATION UNIT

(75) Inventor: Masaya YAMAMOTO, Makinohara-shi (JP)

Correspondence Address: SUGHRUE-265550, 2100 PENNSYLVANIA AVE. NW, WASHINGTON, DC, 20037-3213, US

(73) Assignee: YAZAKI CORPORATION, Tokyo (JP)

(21) Appl. No.: 12/627,547

(22) Filed: Nov. 30, 2009

(30) Foreign Application Priority Data
Dec. 24, 2008 (JP) 2008-327306

(51) Int. Cl. H05K 5/02

(52) U.S. Cl. 174/536; 362/362

(57) ABSTRACT

The present invention provides an illumination unit which has the small number of parts and requires relatively small work hour for its assembling. The illumination unit includes a housing; metal terminals which are supported on said housing and are adapted to be supplied with electric power; and an electronic part mounted on said metal terminals. Each of said metal terminals has a mounting portion which is connected by soldering to terminals of said electronic part.

### CROSS-REFERENCE TO RELATED APPLICATIONS

This application claims priority from Japanese Patent Application No. 2008-327306 filed on Dec. 24, 2008, the entire subject matter of which is incorporated herein by reference.

### TECHNICAL FIELD

This invention relates to an illumination unit mounted, for example, on a roof trim of an automobile (vehicle) so as to illuminate a passenger room of the automobile.

### BRIEF DESCRIPTION OF THE RELATED ART

An interior illumination device having a light-emitting element such as an LED for illumination purposes is mounted on a ceiling of a passenger room of an automobile (vehicle).

As an illumination unit of the above-mentioned interior illumination device, there is related one shown in FIG. 17 (see, for example, JP-A-2008-049936). This illumination unit 901 includes an LED 902 serving as a light-emitting element, a printed circuit board 903 having the LED 902 mounted thereon, a main board 905 connected to the printed circuit board 903 via a wire 904, and a vehicle wire harness 906 connected to the main board 905 so as to supply electric power from a battery thereto.

The wire 904 and the vehicle wire harness 906 are electrically connected to the printed board (circuit member) 903 and the main board (circuit member) 905, using connectors 907.

In the illumination unit 901 of the above construction, electric power is supplied via the vehicle wire harness 906 from a power source such as a battery mounted on the automobile, and the LED 902 is turned on or lighted.

The related illumination unit includes the printed circuit board (circuit member) having the LED mounted thereon, the main board (circuit member) for supplying electric power to the printed circuit board, the wire and connectors connecting the printed circuit board and the main board together, etc., and thus the number of the component parts is large. Much time is required for assembling these component parts together, and therefore there is encountered a problem that the productivity is low.

With the above problem in view, it is an object of this invention to provide an illumination unit in which the number of component parts is reduced, and time and labor required for an assembling operation are reduced.

### SUMMARY

An illumination unit according to a first aspect of the present invention includes a housing; a plurality of metal terminals which are supported on the housing and are supplied with electric power; and an electronic part mounted on the metal terminals. Each of the metal terminals has a mounting portion which is connected by soldering to terminals of the electronic part.

In a second aspect of the invention according to the first aspect, terminal press-fitting holes are formed in the housing, and each of the metal terminals includes a pair of resilient piece portions which are so formed as to be press-fitted into the corresponding terminal press-fitting hole and can be resiliently deformed to be moved toward and away from each other.

In a third aspect of the invention according to the second aspect, the metal terminals are mounted in the housing by insert molding.

In a fourth aspect of the invention according to the first aspect, each of the metal terminals includes an electrical connection portion which cuts into an insulative sheath of a wire to come into contact with a core wire of the wire, and the electrical connection portion has a slot which is open at its one end, and the wire is inserted into the slot through the open end thereof.

In a fifth aspect of the invention according to the first aspect, each of the metal terminals includes a terminal connection portion for connection to a mating metal terminal connected to a wire.

In a sixth aspect of the invention according to the fifth aspect, the housing includes a spacer which is inserted into the housing through an opening formed on an outer wall of the housing to be retained on the housing and also to prevent the mating metal terminals each of which is secured to the wire from being withdrawn from the housing, and the housing further includes retaining pieces each of which retains respectively with the corresponding mating metal terminal.

As described above, according to the first aspect of the invention, the electronic part such as an LED is connected by soldering to the mounting portions of the metal terminals to which electric power is supplied. Therefore, as compared with the related illumination unit including the printed circuit board having the electronic part (such as an LED) mounted thereon, the main board for supplying electric power to the printed circuit board, the wires and connectors connected to the main board, etc., electric power is supplied to the electronic part (such as the LED) via the metal terminals without using such electrical parts of the related illumination unit. Therefore, it is not necessary to provide the printed circuit board, the main board, the connectors, etc. Therefore, there can be obtained the illumination unit in which the number of the component parts can be reduced by omitting the printed circuit board, the main board, the connectors, etc., and also the time and labor required for assembling the component parts together can be reduced.

According to the second aspect of the invention, the metal terminal has the pair of resilient piece portions which are so formed as to be press-fitted into the terminal press-fitting hole in the housing and can be resiliently deformed to be moved toward and away from each other. Therefore, with an easy operation in which the pair of resilient piece portions of the metal terminal are moved toward the terminal press-fitting hole in the housing, and are press-fitted thereinto, the metal terminal can be attached to the housing, and therefore the productivity can be enhanced.

According to the third aspect of the invention, the metal terminals are integrally mounted in the housing by insert molding. Therefore, the metal terminals can be positively mounted in the housing, and also the illumination unit can be formed into a compact design.

According to the fourth aspect of the invention, the electrical connection portion of the metal terminal cuts into the insulative sheath of the wire, covering the core wire thereof, to come into contact with the core wire, and the electrical connection portion has the slot which is open at its one end, and the wire is inserted into the slot through the open end thereof. Therefore, with an easy operation in which the wire is pressed against the metal terminal, the wire can be connected to the metal terminal, and therefore the productivity can be enhanced. Furthermore, the metal terminal and the wire can be directly connected together without using any part such as a connector for connecting the metal terminal and the wire together, and therefore there can be obtained the illumination unit in which the number of the component parts is reduced.

According to the fifth aspect of the invention, the metal terminal includes the terminal connection portion for connection to the mating metal terminal secured to the wire. Therefore, with an easy operation in which the mating metal terminal secured to the wire is inserted into a terminal receiving chamber of the housing, the mating metal terminal can be connected to the metal terminal, and therefore the productivity can be enhanced.

According to the sixth aspect of the invention, the housing includes the spacer which is inserted into the housing through the opening formed through the outer wall thereof to be retained on the housing and also to prevent the mating metal terminals each secured to the wire from being withdrawn from the housing, and the retaining pieces for retaining engagement respectively with the mating metal terminals. Therefore, the mating metal terminals are retained in a double manner by the spacer and the respective retaining pieces, and therefore the mating metal terminals connected to the respective metal terminals can be positively prevented from being withdrawn from the housing.

### BRIEF DESCRIPTION OF THE DRAWINGS

FIG. 1 is a perspective view of a first exemplary embodiment of an illumination unit of the present invention.

FIG. 2 is a cross-sectional view taken along the line I-I of FIG. 1.

FIG. 3 is a view explanatory of an operation for assembling the illumination unit of FIG. 1, showing the manner of press-fitting metal terminals into a housing.

FIG. 4 is a view explanatory of the operation of assembling the illumination unit of FIG. 1, showing the manner of mounting an electronic part on the metal terminals.

FIG. 5 is a view explanatory of the operation for assembling the illumination unit of FIG. 1, showing a condition in which the electronic part is mounted on the metal terminals.

FIG. 6 is a view explanatory of the operation for assembling the illumination unit of FIG. 1, showing the manner of installing wires on the housing.

FIG. 7 is a perspective view of a second exemplary embodiment of an illumination unit of the invention.

FIG. 8 is an exploded perspective view of the illumination unit of FIG. 7.

FIG. 9 is a top plan view explanatory of an operation for assembling the illumination unit of FIG. 7, showing a condition in which metal terminals are mounted in a housing by insert molding.

FIG. 10 is a cross-sectional view taken along the line II-II of FIG. 9.

FIG. 11 is a view explanatory of the operation for assembling the illumination unit of FIG. 7, showing a condition in which an electronic part is mounted on the metal terminals.

FIG. 12 is a cross-sectional view taken along the line III-III of FIG. 11.

FIG. 13 an exploded perspective view of a third exemplary embodiment of an illumination unit of the invention.

FIG. 14 is a top plan view of the illumination unit of FIG. 13.

FIG. 15 is a cross-sectional view taken along the line IV-IV of FIG. 14.

FIG. 16 is a cross-sectional view taken along the line V-V of FIG. 14.

FIG. 17 is a side-elevational view showing a related illumination unit.

### DETAILED DESCRIPTION OF EXEMPLARY EMBODIMENTS OF THE PRESENT INVENTION

### First Exemplary Embodiment

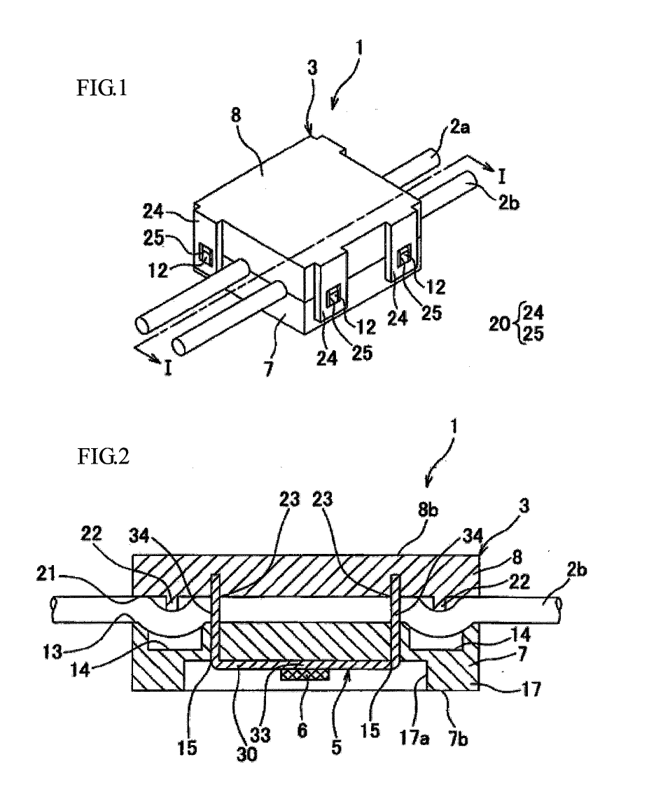

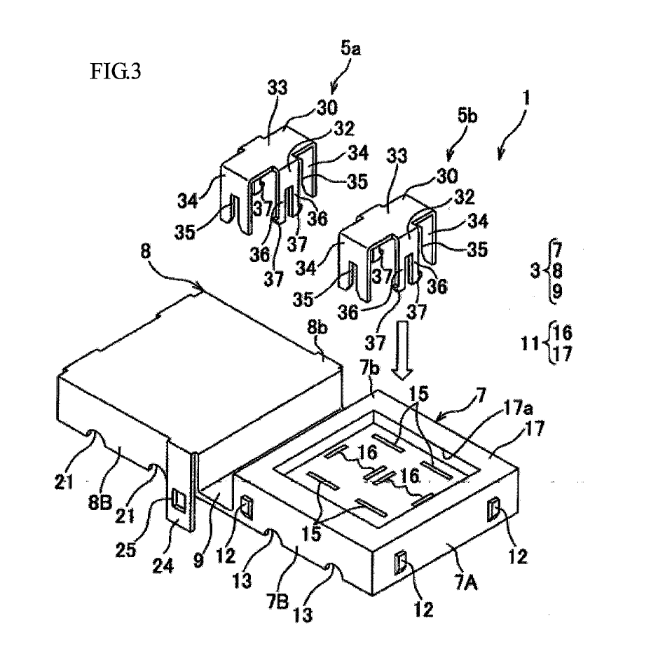

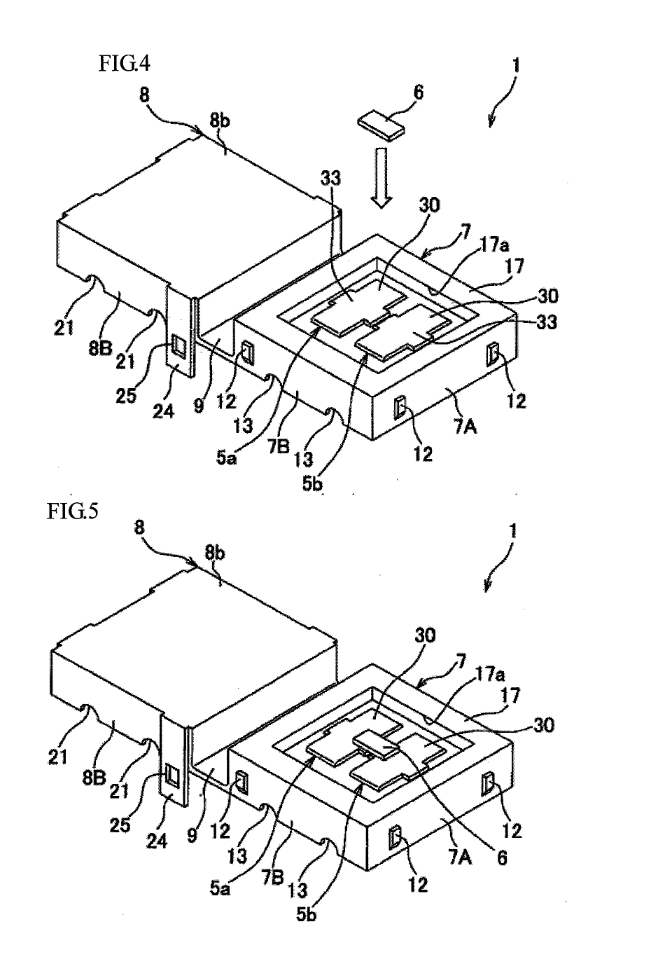

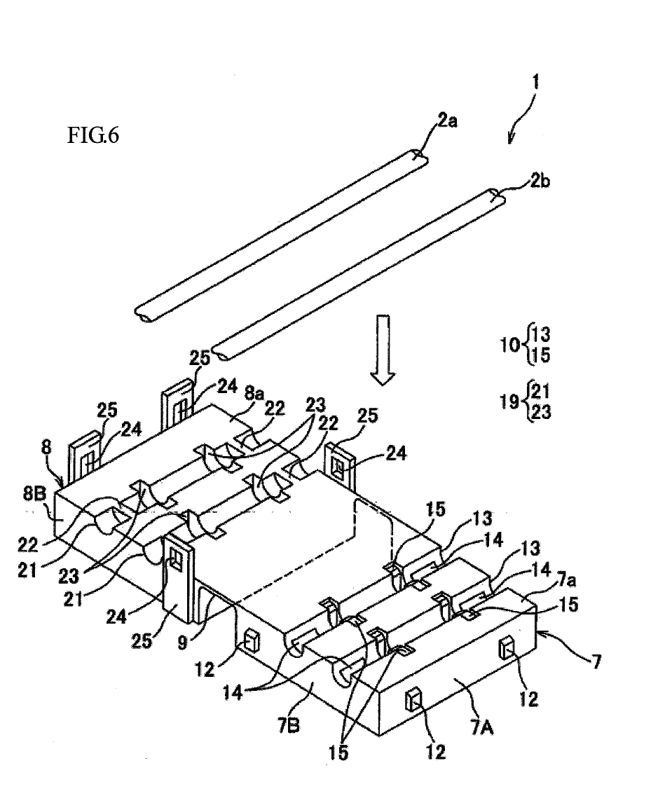

A first exemplary embodiment of an illumination unit of the present invention will now be described with reference to FIGS. 1 to 6. FIG. 1 is a perspective view of the illumination unit of the first embodiment. FIG. 2 is a cross-sectional view taken along the line I-I of FIG. 1. FIG. 3 is a view explanatory of an operation for assembling the illumination unit of FIG. 1, showing the manner of press-fitting metal terminals into a housing. FIG. 4 is a view explanatory of the operation of assembling the illumination unit of FIG. 1, showing the manner of mounting an electronic part on the metal terminals. FIG. 5 is a view explanatory of the operation for assembling the illumination unit of FIG. 1, showing a condition in which the electronic part is mounted on the metal terminals. FIG. 6 is a view explanatory of the operation for assembling the illumination unit of FIG. 1, showing the manner of installing wires on the housing.

The illumination unit 1 of the first embodiment forms an interior illumination device mounted on a roof trim or a door trim mounted on a surface within a passenger room of an automobile (vehicle). The interior illumination device includes a design portion (not shown), and the illumination unit 1.

The design portion is made of a transparent or a translucent synthetic resin, and is formed into a generally flat plate-shape. The design portion, while exposed to the interior of the passenger room, is attached to the roof trim or the door trim

The illumination unit 1 includes the housing 3 made of an insulative synthetic resin, the metal terminals 5 received in the housing 3 and mounted respectively on the wires 2 so as to be supplied with electric power, an LED (Light Emitting Diode) 6 (serving as a light source) mounted on the metal terminals 5, and a lens (not shown) which is in the shape of a paraboloid of revolution and is mounted on the housing 3 to cover the LED 6. The LED 6 corresponds to “electronic part” recited in the appended claims. (This correspondence is of course an not limited example.)

In the illumination unit 1, when electric power is supplied to the LED 6 via the electrically-conductive metal terminals 5, the LED 6 radiates light toward the interior of the passenger room to illuminate the interior of the passenger room.

Each wire 2 is a so-called sheathed wire having an electrically-conductive core wire (not shown) covered with an insulative sheath (not shown). The wire 2 is a round wire having a round cross-section. Two wires 2 are used in the illumination unit 1. One wire 2a is connected to a positive electrode of a power source such as a battery (not shown) mounted on a vehicle body of the automobile. The other wire 2b is connected to a negative electrode of the power source.

The housing 3 includes a pair of clamping portions 7 and 8 for holding the wires 2 therebetween, and a hinge 9 interconnecting the pair of clamping portions 7 and 8. The housing 3 forms a box-like body of the interior illumination device which is to be mounted on the roof trim or the door trim within the passenger room.

The pair of clamping portions 7 and 8 are formed into a box-like shape. The pair of clamping portions 7 and 8 superposed together at their inner surfaces 7a and 8a. In the present invention, the term “the inner surfaces 7a and 8a of the pair of clamping portions 7 and 8” means “the surfaces to be opposed to each other”. A first wire holding portion 10 and a second wire holding portion 19 (which will be described later) receive central portions of the wires 2 through which electric power is supplied, and therefore these central portions are mounted on these wire holding portions.

The clamping portion 7 is integrally connected with the clamping portion 8 through the hinge 9. The clamping portion 7 includes the first wire holding portion 10 formed at the inner surface 7a thereof which is to be superposed on the clamping portion 8, a metal terminal holding portion 11 formed at an outer surface 7b thereof, and engagement projections 12 engageable with respective lock arms 20 (described later) of the clamping portion 8.

The first wire holding portion 10 includes wire receiving grooves 13 for respectively receiving the wires 2, and press-contacting blade passage holes 15 for the passage of press-contacting blades 34 (serving as electrical connection portions) therethrough.

The wire receiving grooves 13 each in the form of a recess are formed in the inner surface 7a of the clamping portion 7, and extend straight. The wire receiving grooves 13 extend in the direction of the width of the housing 3. In the illustrated embodiment, two wire receiving grooves 13 are provided. The two wire receiving grooves 13 extend parallel to each other. When the pair of clamping portions 7 and 8 are superposed together, the wire receiving grooves 13 are opposed respectively to wire receiving grooves 21 formed in the clamping portion 8. Namely, when the pair of clamping portions 7 and 8 are superposed together, longitudinal edges of each wire receiving groove 13 are superposed respectively on longitudinal edges of the corresponding wire receiving groove 21. The wire 2 extends longitudinally through a hole formed by each mating pair of wire receiving grooves 13 and 21.

Wire bend portions 14 each in the form of a recess are further formed in a bottom surface of the wire receiving groove 13. Two wire bend portions 14 are formed in each of the wire receiving grooves 13, and therefore there are provided four wire bend portions 14 in all. Thus, the pair of wire bend portions 14 are formed in each wire receiving groove 13. The pair of wire bend portions 14 are spaced respectively from longitudinally-opposite ends of the wire receiving groove 13. When the pair of clamping portions 7 and 8 are superposed together, the wire bend portions 14 are opposed respectively to wire pressing portions 22 (described later). When the wire pressing portions 22 press the wires 2 extending in and along the respective wire receiving grooves 13, the pressed portions of the wires 2 are bent to be received in the respective wire bend portions 14, and therefore the wires 2 are received in a bent condition in the housing 3.

A distal end portion of each press-contacting blade 34 is passed through the corresponding press-contacting blade passage hole 15 from the outer surface 7b of the clamping portion 7. The press-contacting blade passage holes 15 extend through the clamping portion 7. Each press-contacting blade passage hole 15 has a generally rectangular shape when seen in a plan view. The press-contacting blade passage holes 15 extend in a direction perpendicular to a longitudinal axis of the wire receiving groove 13, that is, perpendicularly intersect the wire receiving groove 13. Two press-contacting blade passage holes 15 are formed at each of the two wire receiving grooves 13, and therefore there are provided four press-contacting blade passage holes 15 in all. Thus, the pair of press-contacting blade passage holes 15 are provided at each wire receiving groove 13. The pair of press-contacting blade passage holes 15 are spaced respectively from the longitudinally-opposite ends of the wire receiving groove 13. The pair of press-contacting blade passage holes 15 are disposed inwardly respectively of the pair of wire bend portions 14 in the longitudinal direction of the wire receiving groove 13. The pair of press-contacting blade passage holes 15 are disposed in parallel spaced relation to each other. When the pair of clamping portions 7 and 8 are superposed together, the press-contacting blade passage holes 15 are opposed respectively to press-contacting blade receiving holes 23 formed in the clamping portion 8. Namely, when the pair of clamping portions 7 and 8 are superposed together, the press-contacting blade passage holes 15 communicate respectively with the press-contacting blade receiving holes 23.

The metal terminal holding portion 11 provided at the outer surface 7b of the clamping portion 7 includes terminal press-fitting holes 16 for the passage of the metal terminals 5 (described later) therethrough, and a frame portion 17 surrounding the terminal press-fitting holes 16 and the press-contacting blade passage holes 15.

Each terminal press-fitting hole 16 is in the form of such a hole that a pair of resilient piece portions 36 of the metal terminal 5 (described later) can be inserted into the hole 16. The terminal press-fitting hole 16 has a generally rectangular shape when seen in a plan view. The pair of terminal press-fitting holes 16 are provided respectively at widthwise-opposite side edges of each wire receiving groove 13. The terminal press-fitting holes 16 extend parallel to the longitudinal axis of the wire receiving groove 13. The pair of terminal press-fitting holes 16 are provided at a generally longitudinally-central portion of the wire receiving groove 13. The pair of terminal press-fitting holes 16 are disposed in parallel opposed relation to each other. Two terminal press-fitting holes 16 are provided at each of the two wire receiving grooves 13, and therefore there are provided four terminal press-fitting holes 16 in all. The pair of terminal press-fitting holes 16 are spaced from each other in a direction perpendicular to the longitudinal axis of the wire receiving groove 13.

The frame portion 17 is formed at the outer peripheral portion of the clamping portion 17, and is formed in an upstanding manner into a square frame-shape. A central portion of the frame portion 17 is open as at 17a, and the terminal press-fitting holes 16 and the press-contacting blade passage holes 15 disposed within the frame portion 17 are exposed through this opening 17a.

Engagement projections 12 are formed at a first side plate portion 7A formed at that edge of the clamping portion 7 facing away from the hinge 9, and also engagement projections 12 are formed respectively at a pair of second side plate portions 7B connected integrally with opposite ends of the first side plate portion 7A. There are provided four engagement projections 12 in all. The pair of second side plate portions 7B are disposed in opposed spaced relation to each other. One pair of engagement projections 12 are formed respectively at opposite end portions of the first side plate portion 7A. Further, the other pair of engagement projections 12 are formed respectively at those end portions of the pair of second side plate portions 7B disposed near to the hinge 9. The engagement projections 12 of a convex shape project from the first and second side plate portions 7A and 7B and therefore project outwardly from the clamping portion 7 and hence from the housing 3.

The clamping portion 8 is integrally connected with the clamping portion 7 through the hinge 9. The clamping portion 8 includes the second wire receiving portion 9 formed at the inner surface 8a thereof which is to be superposed on the clamping portion 7, and the lock arms 20 engageable with the respective engagement projections 12 of the clamping portion 7. The clamping portion 8 can be pivotally moved relative to the clamping portion 7 by the hinge 9. The clamping portion 8 can be pivotally moved about the hinge 9 between a closed position where the inner surfaces 7a and 8a of the clamping portion 7 and 8 are superposed together, with the lock arms 20 engaged respectively with the engagement projections 12 and an open position where the inner surfaces 7a and 8a of the clamping portions 7 and 8 are disposed generally in a common plane.

The second wiring holding portion 19 includes the wire receiving grooves 21 for receiving the respective wires 2, and the press-contacting blade receiving holes 23.

The wire receiving grooves 21 each in the form of a recess are formed in the inner surface 8a of the clamping portion 8, and extend straight. The wire receiving grooves 21 extend in the direction of the width of the housing 3. In the illustrated embodiment, two wire receiving grooves 21 are provided. The two wire receiving grooves 21 extend parallel to each other. When the pair of clamping portions 7 and 8 are superposed together, the wire receiving grooves 21 are opposed respectively to the wire receiving grooves 13 formed in the clamping portion 7. Namely, when the pair of clamping portions 7 and 8 are superposed together, the longitudinal edges of each wire receiving groove 21 are superposed respectively on the longitudinal edges of the corresponding wire receiving groove 13. The wire 2 extends longitudinally through the hole formed by each mating pair of wire receiving grooves 13 and 21. Each wire receiving groove 21 has the wire pressing portions 22 interconnecting the widthwise-opposite side edges (longitudinal edges) thereof.

Two wire pressing portions 22 are provided at each of the two wire receiving grooves 21, and therefore there are provided four wire pressing portions 22 in all. Thus, the pair of wire pressing portions 22 are formed at each wire receiving groove 21. When the pair of clamping portions 7 and 8 are superposed together, the wire pressing portions 22 are opposed respectively to the wire bend portions 14. When the pair of clamping portions 7 and 8 are superposed together, with the wires 2 extending in and along the respective wire receiving grooves 21, the wire pressing portions 22 press the wires 2 toward the respective wire bend portions 14.

When the two clamping portions 7 and 8 are superposed together, the distal end portion of each press-contacting blade 34 is inserted into the corresponding press-contacting blade receiving hole 23 from the outer surface 7b of the clamping portion 7. The press-contacting blade receiving holes 23 each in the form of a recess are formed in the inner surface 8a of the clamping portion 8. Each press-contacting blade receiving hole 23 has a generally rectangular shape when seen in a plan view. The press-contacting blade receiving holes 23 extend in a direction perpendicular to the longitudinal axis of the wire receiving groove 21, that is, perpendicularly intersect the wire receiving groove 21. Two press-contacting blade receiving holes 23 are formed at each of the two wire receiving grooves 21, and therefore there are provided four press-contacting blade receiving holes 23 in all. Thus, the pair of press-contacting blade receiving holes 23 are provided at each wire receiving groove 21. The pair of press-contacting blade receiving holes 23 are spaced respectively from the longitudinally-opposite ends of the wire receiving groove 21. The pair of press-contacting blade receiving holes 23 are disposed inwardly respectively of the pair of wire pressing portions 22 in the longitudinal direction of the wire receiving groove 21. The pair of press-contacting blade receiving holes 23 are disposed in parallel spaced relation to each other. When the pair of clamping portions 7 and 8 are superposed together, the press-contacting blade receiving holes 23 are opposed respectively to the press-contacting blade passage holes 15 formed in the clamping portion 7. Namely, when the pair of clamping portions 7 and 8 are superposed together, the press-contacting blade receiving holes 23 communicate respectively with the press-contacting blade passage holes 15.

The lock arms 20 are formed at a third side plate portion (not shown) formed at that edge of the clamping portion 8 facing away from the hinge 9, and also the lock arms 20 are formed respectively at a pair of fourth side plate portions 8B connected integrally with opposite ends of the third side plate portion. The pair of fourth side plate portions 8B are disposed in opposed spaced relation to each other. There are provided four lock arms 20 in all. One pair of lock arms 20 are formed respectively at opposite end portions of the third side plate portion. Further, the other pair of lock arms 20 are formed respectively at those end portions of the pair of fourth side plate portions 8B disposed near to the hinge 9. Each lock arm 20 includes a plate portion 24, extending from the peripheral edge of the outer surface 8b of the clamping portion 8 and projecting perpendicularly to the inner surface 8a of the clamping portion 8, and a lock hole 25 formed through that end portion of the plate portion 24 remote from the clamping portion 8. The lock hole 25 is formed through the plate portion 24. The lock hole 25 has a generally rectangular shape in a plan view. Each lock arm 20 is retainingly engaged with the corresponding engagement projection 20 such that the engagement projection 20 is fitted in the lock hole 25.

The hinge 9 can be flexed. The hinge 9 is formed integrally with the clamping portions 7 and 8.

The metal terminal 5 is formed by applying a blanking operation, a bending operation, etc., to an electrically-conductive metal sheet made of copper or copper alloy (including brass and beryllium copper). As shown in FIG. 3, the metal terminal 5 is formed into a one-piece construction, and includes the press-contacting blades 34 serving as the electrical connection portions for connection to the wire 2, press-fitting retaining portions 32 each adapted to be attached to the housing 3 and having the pair of resilient piece portions 36, and a body portion 30 interconnecting the press-contacting blades 34 and the press-fitting retaining portions 32 and having a mounting portion 33 for the mounting of the LED 6 thereon.

Two metal terminals 5 are used in the illumination unit 1. One metal terminal 5 is mounted on the wire 2a, and is connected to the positive electrode of the power source (such as the battery) mounted on the vehicle body of the automobile. The other metal terminal 5 is mounted on the wire 2b, and is connected to the negative electrode of the power source.

The body portion 30 has a generally rectangular shape when seen in a plan view. The wire 2 overlies one side (surface) of the body portion 30 and extends parallel to a longitudinal axis of the body portion 30. The mounting portion 33 to which the LED 6 is to be connected is provided at the other side (surface) of the body portion 30.

Terminals (not shown) of the LED 6 are soldered to the mounting portions 33 of the metal terminals 5. Thus, the LED 6 is electrically connected to the metal terminals 5 and is fixed thereto.

The pair of press-contacting blades 34 extend perpendicularly respectively from longitudinally-opposite ends (or edges) of the body portion 30, and are disposed at the one side of the body portion 30. The pair of press-contacting blades 34 are disposed in parallel opposed relation to each other. Each press-contacting blade 34 has a notch 35 which can cut into the sheath of the wire 2 to come into contact with the core wire thereof. The press-contacting blade 34 corresponds to “electrical connection portion” recited in the appended claims. (This correspondence is of course an not limited example.)

The notch 35 extends from the distal end of the press-contacting blade 34 (which is remote from the body portion 30) toward the body portion 30. The notch 35 cuts into the sheath of the wire 2, and comes into contact with the core wire of the wire 2, so that the core wire of the wire 2 is passed through the notch 35 without being severed. The distal end portion of each press-contacting blade 34 is passed through the corresponding press-contacting blade passage holes 15 and is inserted into the corresponding press-contacting blade receiving holes 23. The notch 35 corresponds to “slot” recited in the appended claims. (This correspondence is of course an not limited example.)

The pair of press-fitting retaining portions 32 extend perpendicularly respectively from the widthwise-opposite side edges of the body portion 30 in the same direction as the press-contacting blades 34. The pair of press-fitting retaining portions 32 are disposed in parallel opposed relation to each other. Each press-fitting retaining portion 32 has the pair of resilient piece portions 36. The pair of resilient piece portions 36 are interconnected at their proximal ends disposed near to the body portion 30, and distal end portions thereof remote from the body portion are free. These distal end portions remote from the body portion 30 are slightly spaced from each other. The pair of resilient piece portions 36 can be elastically deformed to be moved toward and away from each other. Projections 37 are formed respectively at the pair of resilient piece portions 36. The projections 37 are formed respectively at the distal ends of the pair of resilient piece portions 36 remote from the body portion 30, and project outwardly away from each other. The pair of resilient piece portions 36 of each press-fitting retaining portion 32 are press-fitted into the corresponding terminal press-fitting hole 16, and are resiliently contacted with an inner surface of the corresponding terminal press-fitting hole 16.

Next, a method of assembling the above illumination unit 1 will be described. First, the distal ends of the press-fitting retaining portions 32 of one metal terminal 5 are moved respectively toward the pair of terminal press-fitting holes 16 formed in the outer surface 7b of the clamping portion 7. Then, the distal ends of the pair of press-contacting blades 34 of the one metal terminal 5 are aligned respectively with the pair of press-contacting blade passage holes 15, and the one metal terminal 5 is pressed against the clamping portion 7. By doing so, the one metal terminal 5 is attached to the clamping portion 7. Thereafter, the other metal terminal 5 is attached to the clamping portion 7, using the above-mentioned method.

Then, the wire 2a is moved toward one wire receiving groove 13 formed in the inner surface 7a of the clamping portion 7. Then, the wire 2a is passed through the notches 35 of the press-contacting blades 34 of the one metal terminal 5. Then, the wire 2b is moved toward the other wire receiving groove 13 in the inner surface 7a of the clamping portion 7. Then, the wire 2b is passed through the notches 35 of the press-contacting blades 34 of the other metal terminal 5b. By doing so, the press-contacting blades 34 of each metal terminal 5 cuts into the insulative sheath of the wire 2 covering the core wire, and comes into contact with the core wire. Thus, each metal terminal 5 is electrically connected to the wire 2.

Then, by pivotally moving the clamping portion 8 about the hinge 9, the inner surfaces 7a and 8a of the two clamping portions 7 and 8 are superposed together. As a result, the wire pressing portions 22 press the sheaths of the wires 2, and bend the wires 2 such that the bent portions of the wires 2 are received respectively in the wire bend portions 14 of the clamping portion 7. Also, the engagement projection 12 are fitted or engaged respectively in the lock holes 25 of the lock arms 20. Thus, the wires 2 is received in the housing 3.

Then, the terminal of the LED 6 is soldered to the mounting portion 33 of the one metal terminal. Then, the other terminal of the LED 6 is soldered to the mounting portion 33 of the other metal terminal 5. Thus, the LED 6 is electrically connected to the two metal terminals 5, and is fixed thereto. In this manner, the illumination unit 1 is completed.

In the first embodiment, the LED 6 is connected by soldering to the mounting portions 33 of the metal terminals 5 to which electric power is supplied. Therefore, as compared with the related illumination unit comprising the printed circuit board having the electronic part mounted thereon, the main board for supplying electric power to the printed circuit board, the wires and connectors connected to the main board, etc., electric power is supplied to the LED 6 via the metal terminals 5 without using such electrical parts of the related illumination unit. Therefore, it is not necessary to provide the printed circuit board, the main board, the connectors, etc. Therefore, there can be obtained the illumination unit 1 in which the number of the component parts can be reduced by omitting the printed circuit board, the main board, the connectors, etc., and also the time and labor required for assembling the component parts together can be reduced.

Furthermore, the press-fitting retaining portion 32 of the metal terminal 5 has the pair of resilient piece portions 36 which are so formed as to be press-fitted into the terminal press-fitting hole 16 and can be resiliently deformed to be moved toward and away from each other. Therefore, with an easy operation in which each pair of resilient piece portions 5 of the metal terminal 5 are moved toward the terminal press-fitting hole 16 and are press-fitted thereinto, the metal terminal 5 can be attached to the housing 3, and therefore the productivity can be enhanced.

Furthermore, each press-contacting blade 34 of the metal terminal 5 cuts into the insulative sheath of the wire 2 covering the core wire thereof, and comes into contact with this core wire. The press-contacting blade 34 has the notch 35 which is open at its one end, and the wire 2 is inserted into the notch 35 through the open end thereof. Therefore, with an easy operation in which the wire 2 is pressed against the metal terminal 5, the wire 2 can be connected to the metal terminal 5, and therefore the productivity can be enhanced. Furthermore, the metal terminal 5 and the wire 2 can be directly connected together without using any part such as a connector for connecting the metal terminal 5 and the wire 2 together, and therefore there can be obtained the illumination unit 1 in which the number of the component parts is reduced.

In the first embodiment, although the metal terminals 5 are mounted on the housing 3 by press-fitting, there can be used the type of metal terminals which are beforehand mounted or embedded in the housing 3 by insert molding.

### The Second Exemplary Embodiment

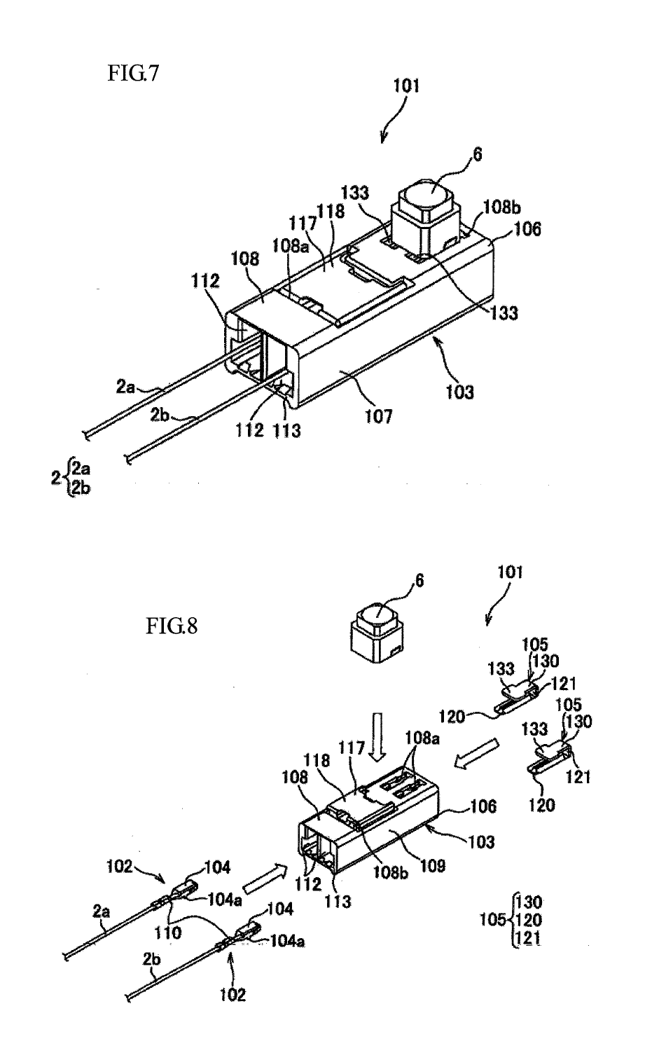

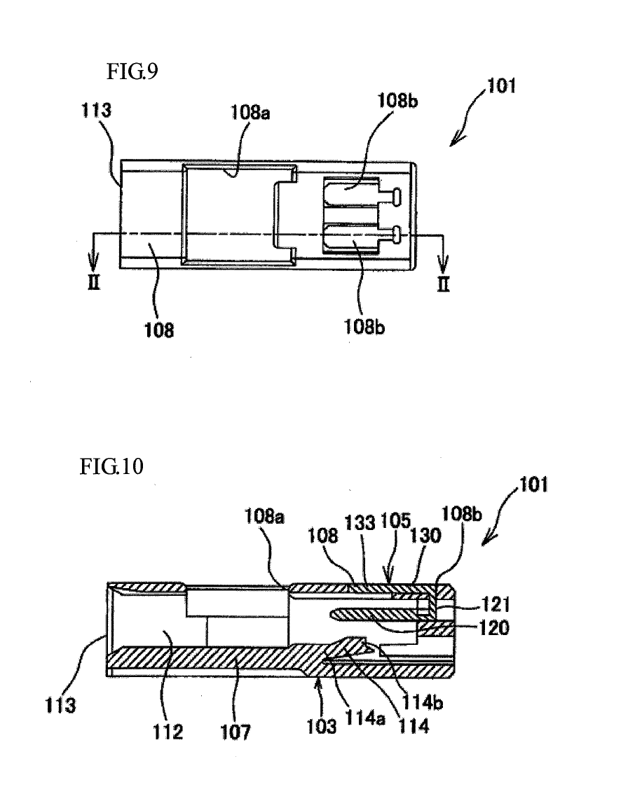

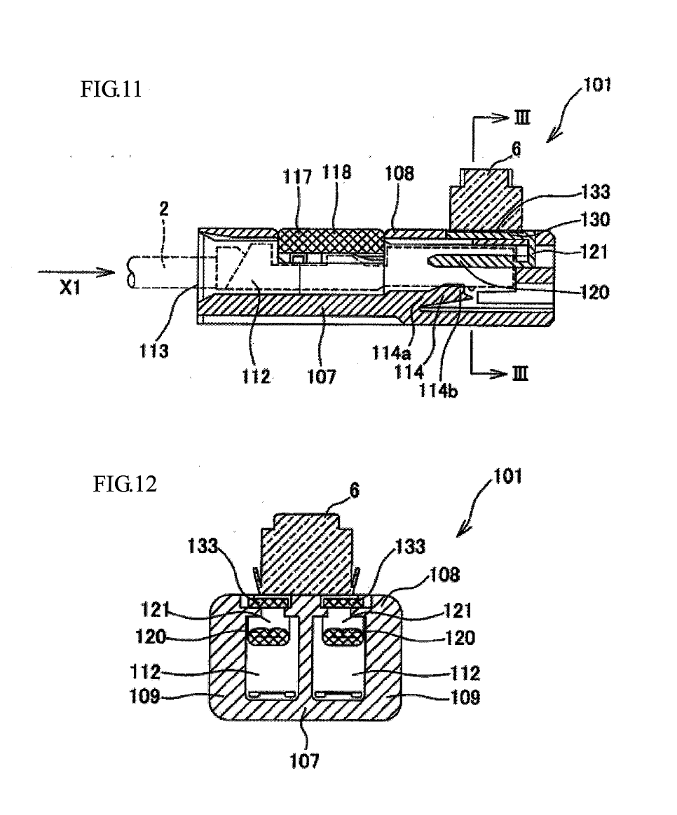

Next, a second exemplary embodiment of an illumination unit of the present invention will be described with reference to FIGS. 7 to 12. FIG. 7 is a perspective view of the illumination unit of the second embodiment. FIG. 8 is an exploded perspective view of the illumination unit of FIG. 7. FIG. 9 is a top plan view explanatory of an operation for assembling the illumination unit of FIG. 7, showing a condition in which metal terminals are mounted in a housing by insert molding. FIG. 10 is a cross-sectional view taken along the line II-II of FIG. 9. FIG. 11 is a view explanatory of the operation for assembling the illumination unit of FIG. 7, showing a condition in which an electronic part is mounted on the metal terminals. FIG. 12 is a cross-sectional view taken along the line III-III of FIG. 11. Those portions identical to the corresponding portions of the first embodiment will be designated by identical reference numerals, respectively, and explanation thereof will be omitted.

Like the illumination unit 1 of the first embodiment, the illumination unit 101 of the second embodiment forms an interior illumination device mounted on a roof trim or a door trim mounted on a surface within a passenger room of an automobile (vehicle). The interior illumination device includes a design portion (not shown), and the illumination unit 101.

The illumination unit 101 includes the housing 103 made of an insulative synthetic resin, the male-type metal terminals 105 (hereinafter referred to as “male terminals”) received in the housing 103 and adapted to be supplied with electric power, an LED (Light Emitting Diode) 6 (serving as a light source) mounted on the male terminals 105, and a lens (not shown) which is in the shape of a paraboloid of revolution and is mounted on the housing 103 to cover the LED 6.

In the illumination unit 101, when electric power is supplied to the LED 6 via the electrically-conductive male terminals 105, the LED 6 radiates light toward the interior of the passenger room to illuminate the interior of the passenger room.

Each of wires 2 is a so-called sheathed wire having an electrically-conductive core wire (not shown) covered with an insulative sheath (not shown). The wire 2 is a round wire having a round cross-section. Two wires 2 are used in the illumination unit 101. One wire 2a is connected to a positive electrode of a power source such as a battery (not shown) mounted on a vehicle body of the automobile. The other wire 2b is connected to a negative electrode of the power source. Mating metal terminals 102 for connection to the respective male terminals 105 are fixedly secured respectively to end portions of the wires 2.

The female-type mating metal terminal 102 (hereinafter referred to as “female terminal) has a one-piece construction, and includes press-fastening piece portions 110 press-fastened to the sheath of the wire 2, and a press-clamping piece portion 104 which is press-clamped or crimped to an exposed portion of the core wire at the end portion of the wire 2 (from which the sheath is removed) to be electrically connected to the core wire and is adapted to be connected to a terminal connection portion 120 of the male terminal 105 (described later). The female terminals 102 are inserted respectively into terminal receiving chambers 112 (described later) in a direction of arrow X1 (that is, in their longitudinal direction), and are received therein. The direction of arrow X1 indicates the direction of inserting of the female terminal 102 (secured to the wire 2) into the terminal receiving chamber 112. The female terminal 102 corresponds to “mating metal terminal” recited in the appended claims. (This correspondence is of course an not limited example.)

The press-clamping piece portion 104 is continuous with the press-fastening piece portions 110, and is formed into a tubular shape so as to receive the terminal connection portion 120 therein. The press-clamping piece portion 104 has a projection 104a formed on and projecting from a lower outer surface thereof, the projection 104a being retainingly engageable with a distal end 114b of a retaining piece 114 (described later) within the terminal receiving chamber 112.

The housing 103 includes a box-like body portion 106. The body portion 106 includes a bottom wall 107, a top wall 108 disposed in opposed spaced relation to the bottom wall 107, and a pair of side walls 109 interconnecting the bottom wall 107 and the top wall 108. The top wall 108 corresponds to “outer wall” recited in the appended claims. (This correspondence is of course an not limited example.)

A first opening 108a for the passage of a spacer 117 (described later) therethrough and second openings 108b for the passage of the LED 6 therethrough are formed through the top wall 108 of the housing 103. The first opening 108a is disposed at a rear portion of the top wall 108 in the direction of arrow X1. The first opening 108a is formed through the top wall 108. The first opening 108a has a generally rectangular shape when seen in a plan view. The outside and inside of the housing 103 communicate with each other through the first opening 108a. Namely, the outside and inside of each terminal receiving chamber 112 communicate with each other through the first opening 108a. The spacer 117 is passed through the first opening 108a. The first opening 108a corresponds to “opening” recited in the appended claims. (This correspondence is of course an not limited example.)

The second openings 108b are disposed at a front portion of the top wall 108 in the direction of arrow X1. The second opening 108b are formed through the top wall 108. The second opening 108b has a slot-like shape. The pair of second openings 108b are provided and are disposed parallel to each other. The outside and inside of each of the two terminal receiving chambers 112 communicate with each other through the corresponding second opening 108b. Mounting portions 133 of the male terminals 105 (described later) are exposed to the outside of the housing 103 through the respective second openings 108b.

The body portion 106 includes the terminal receiving chambers 112 for respectively receiving the female terminals 102 each secured to the wire 2, the spacer 117 which is inserted into the body portion 106 through the first opening 108a to be retained on the body portion 106 (and hence on the housing 103) and also to prevent the female terminals 102 (each secured to the wire 2) from being withdrawn from the respective terminal receiving chambers 112, and a retaining engagement portion (not shown) for retaining engagement with a retaining portion (not shown) of the spacer 117 to retain the spacer 117 on the body portion 106 (and hence on the housing 103).

There are provided two terminal receiving chambers 112. The two terminal receiving chambers 112 are arranged parallel to each other. Each terminal receiving chamber 112 is a linearly-extending space provided within the body portion 106. The terminal receiving chamber 112 is open at its longitudinally-opposite ends to opposite end faces of the body portion 106 (and hence of the housing 103). The female terminal 102 secured to the wire 2 is passed through one open end 113 of the terminal receiving chamber 112.

The retaining pieces 114 are formed respectively within the terminal receiving chambers 112. The retaining piece 114 is formed integrally at its one end 114a on an inner surface of the bottom wall 107 of the terminal receiving chamber 112. When the retaining piece 114 is disposed in its neutral condition (non-elastically deformed condition), the other end (distal end) 114b of the retaining piece 114 is disposed inwardly of the one end 114a in a direction perpendicular to the longitudinal axis of the terminal receiving chamber 112. The other end 114b of the retaining piece 14 can be retainingly engaged with the projection 104a of the press-clamping piece portion 104 of the female terminal 102. The retaining piece 114 can be elastically deformed in such a manner that the other end 114b thereof is moved outwardly within the terminal receiving chamber 112.

When the female terminal 102 is inserted into the terminal receiving chamber 112 in the direction of arrow X1, the retaining piece 114 is pressed by the press-clamping piece portion 104 of the female terminal 102, and is elastically deformed such that the other end 114b is moved outwardly within the terminal receiving chamber 112. Then, when the press-clamping piece portion 104 of the female terminal 102 slides over (or past) the other end 114b, the other end 114b is returned to its neutral position within the terminal receiving chamber 112 because of an elastic restoring force of the retaining piece 114, and is retainingly engaged with the projection 104a of the press-clamping piece portion 104 of the female terminal 102. Thus, the retaining piece 114 prevents the female terminal 102 from being withdrawn from the terminal receiving chamber 112.

The spacer 117 is inserted into the body portion 106 in a direction perpendicular to the longitudinal axes of the terminal receiving chambers 112, and presses the wires 2 in a manner to partially close the interiors of the terminal receiving chambers 112, thereby preventing the wires 2 from being withdrawn from the respective terminal receiving chambers 112 and hence from the housing 103. The spacer 117 includes a box-like spacer body portion 118 for partially closing the interiors of the terminal receiving chambers 112.

The spacer body portion 118 has the same shape in a plan view as the first opening 108a. When the spacer 117 is retained on the housing 103, an outer surface of the spacer body portion 118 is disposed flush with the outer surface of the top wall 108 through which the first opening 108a is formed. The spacer body portion 118 has the retaining portion (not shown) for retaining the spacer 117 on the housing 103.

The retaining portion of the spacer body portion 118 is retainingly engaged with the retaining engagement portion (not shown) on the body portion 106 of the housing 103, thereby retaining the spacer 117 and the housing 103 relative to each other.

The male terminal 105 is formed by applying a blanking operation, a bending operation, etc., to an electrically-conductive metal sheet made of copper or copper alloy (including brass and beryllium copper). The male terminal 105 has a generally recumbent U-shape. The male terminal 105 is formed into a one-piece construction, and includes a male terminal body portion 130 having the mounting portion 133 for the mounting of the LED 6 thereon, the terminal connection portion 120 for insertion into the female terminal 102 (secured to the wire 2) to be connected thereto, and an interconnecting portion 121 interconnecting the male terminal body portion 130 and the terminal connection portion 120. The male terminal 105 corresponds “metal terminal” recited in the appended claims. (This correspondence is of course an not limited example.)

Two metal terminals 105 are used in the illumination unit 101. The wire 2a is connected to one male terminal 105 via the female terminal 102, so that the one male terminal 105 is connected to the positive electrode of the power source such as a battery (not shown) mounted on a vehicle body of the automobile. The wire 2b is connected to the other male terminal 105 via the female terminal 102, so that the other male terminal 105 is connected to the negative electrode of the power source. The two male terminals 105 are received in the terminal receiving chambers 112, respectively.

The male terminal body potion 130 has a generally rectangular shape when seen in a plan view. The male terminal body portion 130 is integrally mounted or embedded in the top wall 108 of the body portion 106 of the housing 103. The male terminal body portion 130 has the mounting portion 133 for the mounting of the LED 6 thereon such that the LED 6 can be mounted on the outer surface of the male terminal 105.

Terminals (not shown) of the LED 6 are soldered to the mounting portions 133. Therefore, the LED 6 is electrically connected to the male terminals 105 and is fixed thereto. The mounting portions 133 of the male terminals 105 are exposed to the outside of the housing 103 through the respective second openings 108b formed in the body portion 106 of the housing 103.

The terminal connection portion 120 is formed into a flat plate-like shape. Longitudinal opposite side edge portions of the terminal connection portion 120 are bent to be opposed to each other, so that the terminal connection portion 120 assumes a generally strip-shape. The terminal connection portion 120 is disposed in opposed relation to the male terminal body portion 130. The terminal connection portion 120 is inserted into the interior of the tubular press-clamping piece portion 140 of the female terminal 120. Thus, the terminal connection portion 120 (and hence the male terminal 105) is connected to the female terminal 102.

The interconnecting portion 121 has a strip-like shape. The interconnecting portion 121 is integrally connected at its one end with one end of the male terminal body 130 in perpendicularly-intersecting relation thereto. Also, the interconnecting portion 121 is integrally connected at the other end thereof with one end of the terminal connection portion 120 in perpendicularly-intersecting relation thereto.

Next, a method of assembling the above illumination unit 101 will be described. The two male terminals 105 are beforehand embedded or molded in the body portion 106 of the housing 103 by insert molding such that the male terminals 105 are disposed respectively in the terminal receiving chambers 112. In this condition, the mounting portions 133 of the male terminals 105 are exposed to the outside of the housing 103 through the respective second openings 108b, and also the ends of the male terminal body portion 130 and terminal connection portion 120 of each male terminal 105 remote from the interconnecting portion 121 are directed toward the one open end 113 of the terminal receiving chamber 112.

Then, the press-clamping piece portion 104 of each female terminal 102 is press-clamped or crimped to the exposed portion of the core wire at the end portion of the wire 2 (from which the sheath is removed). Thus, the wire 2 is electrically connected to the female terminal 102. Then, the press-fastening piece portions 110 are press-fastened onto the outer periphery of the sheath of the wire 2, thereby fixing the female terminal 102 to the wire 2. Then, the female terminal 102 is moved toward the one open end 113 of the terminal receiving chamber 112 in such a manner that the projection 104a of the press-clamping piece portion 104 can be disposed close to the bottom wall 107 of the body portion 106. Then, each female terminal 102 is inserted into the terminal receiving chamber 112 in the direction of arrow X1. At this time, the retaining piece 114 within the terminal receiving chamber 112 is elastically deformed, and then is retainingly engaged with the projection 104a of the press-clamping piece portion 104. As a result, the terminal connection portion 120 of the male terminal 105 is inserted into the press-clamping piece portion 104 of a tubular shape. Thus, the female terminals 102 each secured to the wire 2 are electrically connected respectively to the male terminals 105, and also are received respectively within the terminal receiving chambers 11.

Then, the spacer 117 is inserted into the first opening 108a and is moved in a direction perpendicular to the longitudinal axis of the body portion 106 of the housing 103, and by doing so, the spacer body portion 118 is pressed against the outer surfaces of the wires 2. Then, the retaining portion of the spacer 117 is retainingly engaged with the retaining engagement portion of the body portion 106 of the housing 103. Thus, the spacer 117 is retained on the housing 103. In this condition, the spacer 117 prevents the female terminals 102 (each secured to the wire 2) from being withdrawn from the respective terminal receiving chambers 112 and hence from the housing 103.

Then, one terminal of the LED 6 is passed through one second opening 108b, and is soldered to the mounting portion 133 of one male terminal 105. Then, the other terminal of the LED 6 is passed through the other second opening 108b, and is soldered to the mounting portion 133 of the other male terminal 105. Thus, the LED 6 is electrically connected to the two male terminals 105, and is fixed thereto. In this manner, the illumination unit 101 is completed.

In the second embodiment, the LED 6 is connected by soldering to the mounting portions 133 of the metal terminals (male terminals) 105 to which electric power is supplied. Therefore, as compared with the related illumination unit comprising the printed circuit board having the electronic part mounted thereon, the main board for supplying electric power to the printed circuit board, the wires and connectors connected to the main board, etc., electric power is supplied to the LED 6 via the metal terminals 105 without using such electrical parts of the related illumination unit. Therefore, it is not necessary to provide the printed circuit board, the main board, the connectors, etc. Therefore, there can be obtained the illumination unit 101 in which the number of the component parts can be reduced by omitting the printed circuit board, the main board, the connectors, etc., and also the time and labor required for assembling the component parts together can be reduced.

Furthermore, the metal terminals 105 are integrally mounted in the housing 103 by insert molding. Therefore, the metal terminals 105 can be positively mounted in the housing 103, and also the illumination unit 1 can be formed into a compact design.

Furthermore, the male terminal 105 includes the terminal connection portion 120 for connection to the female terminal 102 secured to the wire 2. Therefore, with an easy operation in which the female terminal 102 secured to the wire 2 is inserted into the terminal receiving chamber 112, the female terminal 102 can be connected to the terminal connection portion 120 of the male terminal 105, and therefore the productivity can be enhanced.

Furthermore, the housing 103 includes the spacer 117 which is inserted into the housing 103 through the first opening 108a formed through the top wall 108 thereof and is retained on the housing 103, and also prevents the female terminals 102 each secured to the wire 2 from being withdrawn from the housing 103, and the retaining pieces 114 for respectively retaining the female terminals 102. Therefore, the female terminals 102 connected to the respective male terminals 105 can be positively prevented from being withdrawn from the housing 103.

In the second embodiment, although the male terminals (metal terminals) 105 are embedded in the body portion 106 of the housing 103 by insert molding, and are provided in the respective terminal receiving chambers 112, there can be used the type of male terminals 105 which are press-fitted into the respective terminal receiving chambers 112 from the other open ends thereof remote from the one open ends 113 thereof.

### The Third Exemplary Embodiment

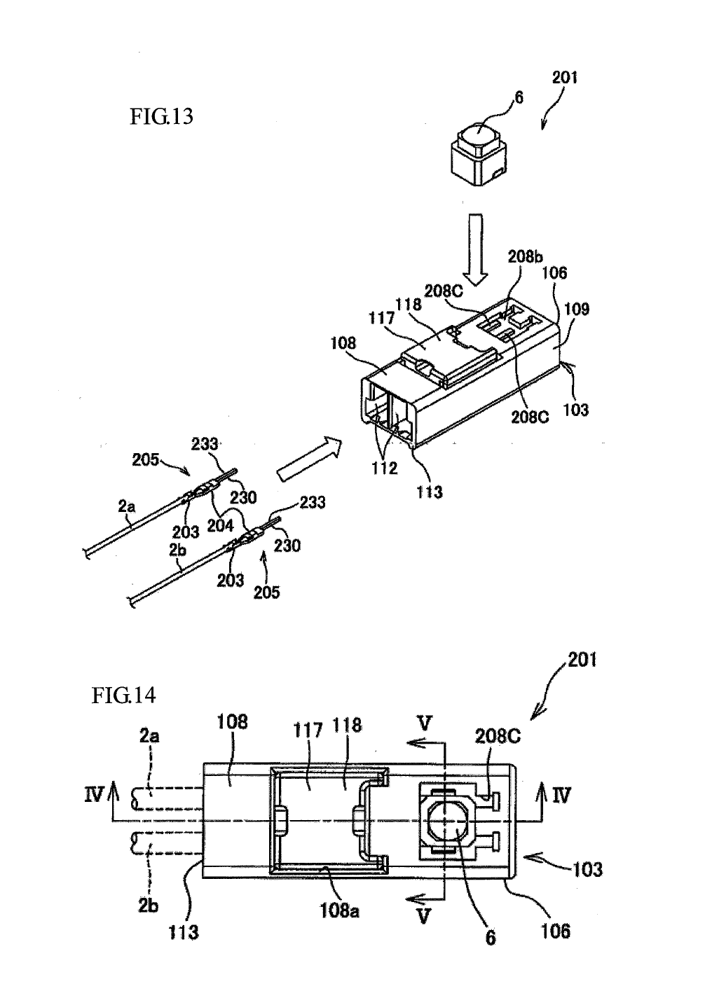

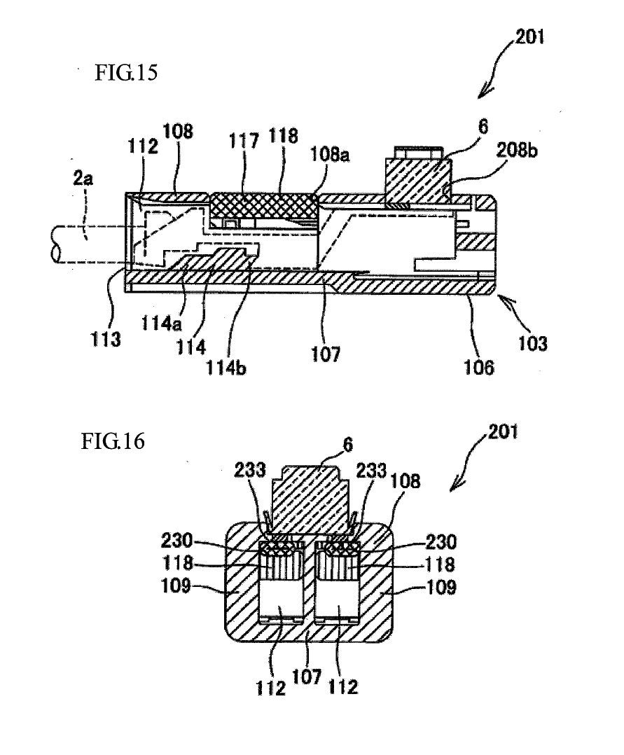

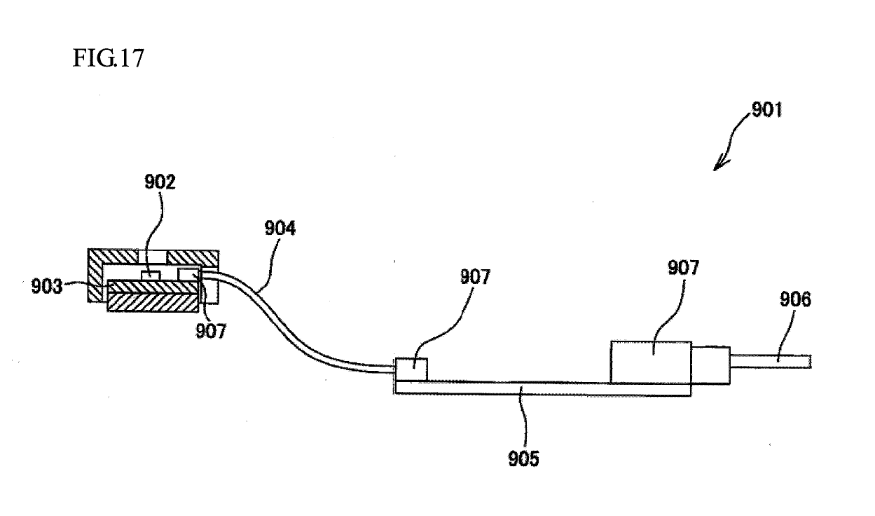

Next, a third exemplary embodiment of an illumination unit of the present invention will be described with reference to FIGS. 13 to 16. FIG. 13 an exploded perspective view of the illumination unit of the third exemplary embodiment. FIG. 14 is a top plan view of the illumination unit of FIG. 13. FIG. 15 is a cross-sectional view taken along the line IV-IV of FIG. 14. FIG. 16 is a cross-sectional view taken along the line V-V of FIG. 14. Those portions identical to the corresponding portions of the above second embodiment will be designated by identical reference numerals, respectively, and explanation thereof will be omitted.

Like the illumination unit 1 of the first embodiment and the illumination unit 101 of the second embodiment, the illumination unit 201 of the third embodiment forms an interior illumination device mounted on a roof trim or a door trim mounted on a surface within a passenger room of an automobile (vehicle). The interior illumination device includes a design portion (not shown), and the illumination unit 201.

The illumination unit 201 includes a housing 103 made of an insulative synthetic resin, metal terminals 205 received in the housing 103 and adapted to be supplied with electric power, an LED (Light Emitting Diode) 6 (serving as a light source) mounted on the metal terminals 205, and a lens (not shown) which is in the shape of a paraboloid of revolution and is mounted on the housing 103 to cover the LED 6.

In the illumination unit 201, when electric power is supplied to the LED 6 via the electrically-conductive metal terminals 205, the LED 6 radiates light toward the interior of the passenger room to illuminate the interior of the passenger room.

Each of wires 2 is a so-called sheathed wire having an electrically-conductive core wire (not shown) covered with an insulative sheath (not shown). The wire 2 is a round wire having a round cross-section. Two wires 2 are used in the illumination unit 201. One wire 2a is connected to a positive electrode of a power source such as a battery (not shown) mounted on a vehicle body of the automobile. The other wire 2b is connected to a negative electrode of the power source. The metal terminals 205 are fixedly secured respectively to end portions of the wires 2.

The housing 103 includes a box-like body portion 106. The body portion 106 includes a bottom wall 107, a top wall 108 disposed in opposed spaced relation to the bottom wall 107, and a pair of side walls 109 interconnecting the bottom wall 107 and the top wall 108. A first opening 108a for the passage of a spacer 117 (described later) therethrough and a LED support portion 208b for the mounting of the LED 6 thereon are provided at the top wall 108 of the housing 103.

The first opening 108a is disposed at a rear portion of the top wall 108 in a direction of arrow X1. The first opening 108a is formed through the top wall 108. The first opening 108a has a generally rectangular shape when seen in a plan view. The outside and inside of the housing 103 communicate with each other through the first opening 108a. Namely, the outside and inside of each terminal receiving chamber 112 communicate with each other through the first opening 108a. The spacer 117 (described later) is passed through the first opening 108a.

The LED support portion 208b is disposed at a front portion of the top wall 108 in the direction of arrow X1. The LED support portion 208b in the form of a recess is formed in an outer surface of the top wall 108. Second openings 208c are formed in a bottom surface of the LED support portion 208b. The LED 6 is adapted to be placed on the LED support portion 208b.

The second openings 208c are formed through the top wall 108. The second opening 208c has a slot-like shape when seen in a plan view. There are provided the pair of second openings 208c. The pair of second openings 208c are disposed parallel to each other. The outside and inside of each of the two terminal receiving chambers 112 communicate with each other through the corresponding second opening 208c. Mounting portions 233 of the metal terminals 205 (described later) are exposed to the outside of the housing 103 through the respective second openings 208c.

The body portion 106 includes the terminal receiving chambers 112 for respectively receiving the metal terminals 205 each secured to the wire 2, the spacer 117 which is inserted into the body portion 106 through the first opening 108a to be retained on the body portion 106 (and hence on the housing 103) and also to prevent the metal terminals 205 (each secured to the wire 2) from being withdrawn from the respective terminal receiving chambers 112, and a retaining engagement portion (not shown) for retaining engagement with a retaining portion (not shown) of the spacer 117 to retain the spacer 117 on the body portion 106 (and hence on the housing 103).

There are provided two terminal receiving chambers 112. The two terminal receiving chambers 112 are arranged parallel to each other. Each terminal receiving chamber 112 is a linearly-extending space provided within the body portion 106. The terminal receiving chamber 112 is open at its longitudinally-opposite ends to opposite end faces of the body portion 106 (and hence of the housing 103). The metal terminal 205 secured to the wire 2 is passed through one open end 113 of the terminal receiving chamber 112.

Retaining pieces 114 are formed respectively within the terminal receiving chambers 112. The retaining piece 114 is formed integrally at its one end 114a on an inner surface of the bottom wall 107 of the terminal receiving chamber 112. When the retaining piece 114 is disposed in its neutral condition (non-elastically deformed condition), the other end (distal end) 114b of the retaining piece 114 is disposed inwardly of the one end 114a in a direction perpendicular to the longitudinal axis of the terminal receiving chamber 112. The other end 114b of the retaining piece 14 can be retainingly engaged with a press-clamping piece portion 204 of the metal terminal 205. The retaining piece 114 can be elastically deformed in such a manner that the other end 114b thereof is moved outwardly within the terminal receiving chamber 112.

When the metal terminal 205 is inserted into the terminal receiving chamber 112 in the direction of arrow X1, the retaining piece 114 is pressed by the press-clamping piece portion 204 of the metal terminal 205, and therefore is elastically deformed such that the other end 114b is moved outwardly within the terminal receiving chamber 112. Then, when the press-clamping piece portion 204 of the metal terminal 205 slides over (or past) the other end 114b, the other end 114b is returned to its neutral position within the terminal receiving chamber 112 because of an elastic restoring force of the retaining piece 114, and is retainingly engaged with the press-clamping piece portion 204 of the metal terminal 205. Thus, the retaining piece 114 prevents the metal terminal 205 from being withdrawn from the terminal receiving chamber 112.

The spacer 117 is inserted into the body portion 106 in a direction perpendicular to the longitudinal axes of the terminal receiving chambers 112, and presses the wires 2 in a manner to partially close the interiors of the terminal receiving chambers 112, thereby preventing the wires 2 from being withdrawn from the respective terminal receiving chambers 112 and hence from the housing 103. The spacer 117 includes a box-like spacer body portion 118 for partially closing the interiors of the terminal receiving chambers 112.

The spacer body portion 118 has the same shape in a plan view as the first opening 108a. When the spacer 117 is retained on the housing 103, an outer surface of the spacer body portion 118 is disposed flush with the outer surface of the top wall 108 through which the first opening 108a is formed. The spacer body portion 118 has the retaining portion (not shown) for retaining the spacer 117 on the housing 103.

The retaining portion of the spacer body portion 118 is retainingly engaged with the retaining engagement portion (not shown) on the body portion 106 of the housing 103, thereby retaining the spacer 117 and the housing 103 relative to each other.

The metal terminal 205 is formed by applying a blanking operation, a bending operation, etc., to an electrically-conductive metal sheet made of copper or copper alloy (including brass and beryllium copper). The metal terminal 205 has a generally bar-shape. The metal terminal 205 is formed into a one-piece construction, and includes press-fastening piece portions 203 press-fastened onto the outer periphery of the sheath of the wire 2 to thereby fix the metal terminal 205 to the wire 2, the press-clamping piece portion 204 which is continuous with the press-fastening piece portions 203 and is press-clamped or crimped to an exposed portion of the core wire at the end portion of the wire 2 (from which the sheath is removed) to be electrically connected to the core wire, and a terminal body portion 230 extending from the press-clamping piece portion 204 and having the mounting portion 233 for connection to the LED 6.

The metal terminals 205 are inserted into the respective terminal receiving chambers 112 in the direction of arrow X1, and are received therein. The direction of arrow X1 indicates the direction of inserting of the metal terminal 205 into the terminal receiving chamber 112.

Two metal terminals 205 are used in the illumination unit 201. One metal terminal 205 is secured and connected to the wire 2a, and is connected to the positive electrode of the power source such as a battery (not shown) mounted on the vehicle body of the automobile. The other metal terminal 205 is secured and connected to the wire 2b, and is connected to the negative electrode of the power source. The two metal terminals 205 are received in the terminal receiving chambers 112, respectively.

The terminal body potion 230 has a generally rectangular shape when seen in a plan view. The terminal body portion 230 has the mounting portion 233 formed on an upper surface thereof, and the LED 6 is connected to this mounting portion 233.

Terminals (not shown) of the LED 6 are soldered to the mounting portions 233 of the two metal terminals 205. Therefore, the LED 6 is electrically connected to the metal terminals 205 and is fixed thereto.

Next, a method of assembling the above illumination unit 201 will be described. The press-clamping piece portion 204 of each metal terminal 205 is press-clamped or crimped to the exposed portion of the core wire at the end portion of the wire 2 (from which the sheath is removed). Thus, the wire 2 is electrically connected to the metal terminal 205. Then, the press-fastening piece portions 203 are press-fastened onto the outer periphery of the sheath of the wire 2, thereby fixing the metal terminal 205 to the wire 2. Then, the distal end of the metal terminal 205 remote from the end portion of the wire 2 is moved toward the one open end 113 of the terminal receiving chamber 112. Then, each metal terminal 205 is inserted into the terminal receiving chamber 112 in the direction of arrow X1. As a result, the retaining piece 114 within the terminal receiving chamber 112 is elastically deformed, and then is retainingly engaged with the press-clamping piece portion 204. Thus, the metal terminals 205 secured to the respective wires 2 are received within the respective terminal receiving chambers 112.

Then, the spacer 117 is inserted into the first opening 108a and is moved in a direction perpendicular to the longitudinal axis of the body portion 106 of the housing 103, and by doing so, the spacer body portion 118 is pressed against the outer surfaces of the wires 2. Then, the retaining portion of the spacer 117 is retainingly engaged with the retaining engagement portion of the body portion 106 of the housing 103. Thus, the spacer 117 is retained on the housing 103. In this condition, the spacer 117 prevents the metal terminals 205 (each secured to the wire 2) from being withdrawn from the respective terminal receiving chambers 112 and hence from the housing 103.

Then, the LED 6 is placed or mounted on the LED support portion 208b. Then, one terminal of the LED 6 is soldered to the mounting portion 233 of one metal terminal 205 exposed through one second opening 208c. Then, the other terminal of the LED 6 is soldered to the mounting portion 233 of the other metal terminal 205 exposed through the other second opening 208c. Thus, the LED 6 is electrically connected to the two metal terminals 205, and is fixed thereto. In this manner, the illumination unit 201 is completed.

In the third embodiment, the LED 6 is directly connected by soldering to the mounting portions 233 of the metal terminals 205 to which electric power is supplied. Therefore, as compared with the related illumination unit comprising the printed circuit board having the electronic part mounted thereon, the main board for supplying electric power to the printed circuit board, the wires and connectors connected to the main board, etc., electric power is supplied to the LED 6 via the metal terminals 205 without using such electrical parts of the related illumination unit. Therefore, it is not necessary to provide the printed circuit board, the main board, the connectors, etc. Therefore, there can be obtained the illumination unit 201 in which the number of the component parts can be reduced by omitting the printed circuit board, the main board, the connectors, etc., and also the time and labor required for assembling the component parts together can be reduced.

Furthermore, the housing 103 includes the spacer 117 which is inserted into the housing 103 through the first opening 108a formed through the top wall 108 thereof and is retained on the housing 103, and also prevents the metal terminals 205 each secured to the wire 2 from being withdrawn from the housing 103, and the retaining pieces 114 for respectively retaining the metal terminals 205. Therefore, the metal terminals 205 can be positively prevented from being withdrawn from the housing 103.

In the above first to third embodiments, although the LED 6 is used as “the electronic part” recited in the appended claims, the electronic part is not limited to the LED. For example, it can be replaced by a switch used in an operation of any suitable associated equipment.

The above embodiments merely show representative forms of the invention, and the invention is not limited to the above embodiments. Namely, various modifications can be made without departing from the subject matter of the invention.

What is claimed is:

1. An illumination unit comprising:
a housing;
a plurality of metal terminals which are supported on said housing and are supplied with electric power; and
an electronic part mounted on said metal terminals;
wherein each of said metal terminals has a mounting portion which is connected by soldering to terminals of said electronic part.

2. The illumination unit according to claim 1, wherein a plurality of terminal press-fitting holes are formed in said housing, and each of said metal terminals includes a pair of resilient piece portions which are so formed as to be press-fitted into the corresponding terminal press-fitting hole and can be resiliently deformed in a direction toward and away from each other.

3. The illumination unit according to claim 1, wherein said metal terminals are mounted in said housing by insert molding.

4. The illumination unit according to claim 1, wherein each of said metal terminals includes an electrical connection portion which cuts into an insulative sheath of a wire to come into contact with a core wire of the wire, and said electrical connection portion has a slot which is open at its one end, and said wire is inserted into said slot through said open end thereof.

5. The illumination unit according to claim 1, wherein each of said metal terminals includes a terminal connection portion for connection to a mating metal terminal secured to a wire.

6. The illumination unit according to claim 5, wherein said housing includes a spacer which is inserted into said housing through an opening formed on an outer wall of said housing to be retained on said housing and to prevent said mating metal terminals each of which is secured to respective wire from being withdrawn from said housing, and said housing further includes retaining pieces each of which retains respectively with corresponding said mating metal terminal.
